(19) United States
(12) Patent Application Publication
(10) Pub. No.: US 2011/0049379 A1
(43) Pub. Date: Mar. 3, 2011

(54) NEUTRON DETECTORS MADE OF INORGANIC MATERIALS AND THEIR METHOD OF FABRICATION

(75) Inventor: Daniel Moses, Santa Barbara, CA (US)

(73) Assignee: THE REGENTS OF THE UNIVERSITY OF CALIFORNIA, Oakland, CA (US)

(21) Appl. No.: 12/869,388

(22) Filed: Aug. 26, 2010

Related U.S. Application Data
(60) Provisional application No. 61/237,080, filed on Aug. 26, 2009.

(51) Int. Cl. G01T 3/00; H01L 31/18; H01L 31/115

(52) U.S. Cl. 250/390.01; 438/56; 257/428; 257/E21.211; 257/E31.086

(57) ABSTRACT

A neutron detector, or array of neutron detectors, and method for fabricating same, having active region comprised of inorganic materials such as semiconductors and/or small particles and/or molecules. The detector active region is comprised of a layer or multi-layer heterojunction structure such as p-n junction wherein at least one layer comprises a composite of host semiconductor material in which neutron sensitizing guest material is distributed in all directions throughout the host semiconductor. This composite layer contains neutron capturing atoms such as ¹⁰B, ⁶Li, ¹⁵⁷Gd, ²³⁵U, ²³⁹Pu, ⁵¹V , and ¹⁰³Rh. The semiconductor host and other semiconductor layers transports carriers excited as a result of neutron absorption in the detector active region.

### CROSS REFERENCE TO RELATED APPLICATIONS

This application claims the benefit under 35 U.S.C. Section 119(e) of the following co-pending and commonly-assigned application:

U.S. Provisional Application Ser. No. 61/237,080, filed on Aug. 26, 2009, by Daniel Moses, entitled “NEUTRON DETECTORS MADE OF INORGANIC MATERIALS, AND THEIR METHOD OF FABRICATION,” attorney's docket number 30794.326-US-P1 (2009-536-1),

which application is incorporated by reference herein.

### BACKGROUND OF THE INVENTION

1. Field of the Invention

The present application relates generally to neutron detectors, and specifically neutron detectors based on inorganic materials.

2. Description of the Related Art

Researchers have sought more effective neutron detection for use in, for example, homeland security, such as the detection of emitted neutrons by Special Nuclear Materials (e.g. uranium and plutonium). However, effective detection of neutrons is a challenge, because neutron detection typically suffers from problems arising from background noise, low detection rates, and the charge neutrality of neutrons.

Earlier patents issued or earlier patent applications describe different neutron active regions and/or different neutron detector fabrication methods.

For example U.S. Pat. No. 4,419,578 issued on Dec. 6, 1983 to inventor K. A. Kress discloses a neutron detector comprising Schottky or p-n rectifying junctions, in which the semiconductor layer in the former junction and one of the semiconductor layers in the latter junction is made of semiconductor material containing hydrogen.

A second example, U.S. Pat. No. 5,726,453 issued on Mar. 10, 1998 to inventors R. G. Lott et al discloses a neutron detector that uses a neutron sensitizing layer (a neutron converter layer) that is deposited on top of a semiconductor device (with a preferred semiconductor material for the active region is silicon carbide).

Such a configuration of neutron detector where the neutron converter layer is on top of a semiconductor rectifying junction does not facilitate sufficiently efficient neutron detectors since in order to have a sufficient neutron capture probability the thickness of the neutron converter layer needs to be relatively large. The relatively short range of travel of the secondary reaction product particles generated by the fission reaction following a neutron capture and the energy attenuation of these secondary particles contribute to the typically low neutron detection efficiency.

A third example, U.S. Pat. No. 6,545,281, issued on Apr. 8, 2003 to inventors D. McGregor et al discloses a neutron detector comprising of detector substrate made of semiconductors such as Si, SiC, amorphous Si, GaAs, or diamond in which cavities, or holes, are prepared. A neutron sensitizing material such as of elemental or any compound of, ¹⁰B, ⁶Li, ⁶LiF, U, or Gd is deposited on the surface of the detector material so as to be disposed within the cavities therein. Preparing such a detector with cavities as well as filling these cavities requires additional high cost processing steps.

A fourth example, U.S. Pat. No. 7,271,389 issued on Sep. 18, 2007 to inventors H. L. Hughes et al discloses a neutron detector that uses a neutron sensitizing layer (a neutron converter layer) that is deposited on top of a semiconductor device. As indicated in the second example above, such configuration of the neutron detector does not facilitate sufficiently efficient neutron detectors.

A fifth example, U.S. Pat. No. 7,372,009 issued on May 13, 2008 to inventors J. R. Losee et al discloses solid state thermal neutron detector that uses neutron detector active region comprising of compounds that contain neutron sensitizing atoms; these compounds are limited to very specific material selected from the group that includes cubic boron nitride, gadolinium oxide, lithium tantalate, and lithium niobate. Such detectors are very limited by required fabrication techniques and are of very high cost.

A sixth example, U.S. Pat. No. 6,388,260 issued on May 14, 2002 to inventors F. Patrick Doty et al discloses Solid state neutron detector and its fabrication method that utilize two compounds: crystals or poly-crystals of lithium tetraborate or alpha-barium borate. Such detectors are limited to these compounds, materials that do not exhibit very high carrier mobility and in which the excitation energy for an electron-hole pair is relatively high, features that limit the detector sensitivity.

A seventh example, U.S. Pat. No. 6,876,711, issued on Apr. 5, 2005 to inventors Wallace et al discloses Neutron detector utilizing sol-gel absorber deposited on top of a microchannel plate, a channeltron, an avalanche photodiode, a scintillator, or a silicon surface barrier detector. Such a detector is limited in sensitivity due to limitations similar the ones described in the above second example.

An eighth example, U.S. Pat. No. 6,727,504, issued on Apr. 27, 2004 to inventor F. Patrick Doty discloses a Boron nitride solid state neutron detector comprising a detector active layer made of hexagonal boron nitride. This material is difficult to process and such a detector is very limited and expensive as with other examples mentioned herein.

A ninth example, U.S. 2006/0255282, patent application filed on Apr. 27, 2006 by inventors R. J. Nikolic et al discloses semiconductor materials matrix for neutron detection comprising a semiconductor material in which predetermined holes, or pillars are prepared, by various etching related techniques, and filled with neutron sensitizing material. The general approach is similar in concept to the one described in the above third example with one main difference, that the dimension of these holes and pillars structures is in the range between micrometer and nanometer. The described distribution of the neutron sensitizing material and fabrication routes of such structures involves photolithography techniques or e-beam lithography, resulting in high-cost devices.

A tenth example, U.S., patent application No. 2009/0302226 filed on Feb. 8, 2006 by inventors Michael M. Schieber et al discloses neutron detection comprising a semiconductor material detector with an active region formed of a polycrystalline semiconductor material sensitive to neutron and alpha particles radiation imbedded in a binder. The particulate semiconductor material containing at least one isotope sensitive to neutron radiation, selected from a group including ¹⁰B ⁶Li ¹¹³Cd ¹⁵⁷Gd. ¹⁹⁹Hg. The binder can be either an organic insulator such as polymer polystyrene, polypropylene, Humiseal™. and Nylon-6, or inorganic insulator selected from B₂O, PbO/B₂O₃, Bi₂O/PbO, Borax glass, Bismuth Borate glass and Boron Oxide based glass. Such a detector contains a different host material (e.g. insulator) which results in a limited detector sensitivity.

Consequently, there is a need in the art for more effective neutron detectors. In particular, there is a need for large area, lightweight neutron detectors that can be manufactured in a cost effective way.

### SUMMARY OF THE INVENTION

The present invention discloses approaches to constructing a neutron detector or array of neutron detectors comprising an active region of one solid layer or multiple solid layers where at least one layer is a composite containing host inorganic semiconductor (such as ZnSe, ZnO, CuInS₂ CdSe, CdS, Si, GaP, GaAs, etc.) and guest material that contains atoms such as ¹⁰B, ⁶Li, ¹⁵⁷Gd, ²³⁵U, ²³⁹Pu, ⁵¹V, and ¹⁰³Rh that have high cross section for capturing thermal neutrons and that is distributed in all directions throughout the host semiconductor and that such a layer can be fabricated using film deposition using solution or paste.

The neutron active region can comprise multi-layer structures such as p-n junction, p-i-n junction, Schottky junction, or other junctions in which at least one layer comprises a host-guest composite layer in which additional doped or non-doped semiconductor layers facilitate the above rectifying junctions. Using a solution or a paste containing small colloids and/or precursor molecules of the host semiconductor and of the guest neutron sensitizing materials, or any combination of colloids and precursor molecules of these materials, facilitates simplified methods for low cost, fabricating of large area and lightweight neutron detectors using methods that include non-vacuum film deposition such as printing, doctor blade, screen printing, spray pyrolysis, roll coating, slot die coating, gravure printing, flexographic drum printing, inkjet printing, electrodeposition, chemical bath deposition, and other film deposition methods.

Deposition of one or multiple doped or non doped layers onto doped or non-doped (crystalline or polycrystalline) semiconductor substrate (wafer) or semiconductor film on a substrate are also possible approaches to fabricating multi-layered heterostructures such as p-n or p-i-n junction that comprises the neutron detector active region. Film deposition onto heated substrate in addition to one or more post-film deposition heating treatment steps can be utilized to initiate or accelerate material synthesis, eliminate volatile materials, and facilitate densified film formation of the host semiconductor composite layer or any other layers in the multi-layers structure through synthesis by chemical reaction of the precursor materials of the host semiconductor and possibly of the guest material, and sintering of the colloids formed by this chemical reaction or sintering of the colloids that were added to the starting solution or paste.

Other post film fabrication treatments may be used in order to enhance carrier transport properties and optimize doping levels in the host semiconductor composite layer and/or other semiconductor layers (for a detector active region comprising a multi-layer structure), such as dipping the fabricated film(s) in solution containing specific molecules (e.g. dipping CdS films in solution containing chlorine molecules), or exposure of the densified film(s) to gases (e.g. POCl₃, O₂, and N₂ used for silicon films in order to enhance doping level or create silicon oxide or silicon nitride films, respectively) in conjunction with heat treatment to facilitate diffusion of the gas molecules in the solid film(s).

### BRIEF DESCRIPTION OF THE DRAWINGS

Referring now to the drawings in which like reference numbers represent corresponding parts throughout:

FIGS. 1A is a schematic block diagrams of the neutron detector according to one or more embodiments of the present invention.

FIGS. 1B-1C are schematic block diagrams of the neutron detector according to several embodiments of the present invention.

FIG. 2 illustrates the spectrum of the photoconductive responsivity (in units of A/W) measured in a CdSe film made in accordance with one or more embodiments of the present invention.

FIG. 3 illustrates the time dependence of the transient photocurrent measured in the CdSe sample of FIG. 2.

FIG. 4 illustrates a multi channel analyzer spectral response in energy bins range 0-101 obtained from a neutron detector made in accordance with one or more embodiments of the present invention.

FIG. 5 illustrates a multi channel analyzer spectral response in energy bins range 101-1024 obtained from the neutron detector of FIG. 4.

FIG. 6 illustrates a process chart in accordance with one or more embodiments of the present invention.

FIG. 7 illustrates a process chart in accordance with one or more embodiments of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

A common geometry used for neutron detectors comprises a planar semiconductor over which a neutron converting (neutron sensitizing material) film is deposited. Following a neutron capture in this film, energetic ionizing reaction products (e.g. alpha particles) are generated and as these particles travel through the top converting film and enter the semiconductor material they can generate charge carrier (electron-hole pairs) excitations and give rise to a detection signal. The performance of such geometry is limited due to tradeoff between the need to have sufficient neutron capture probability (and thus relatively thick top neutron converting film) and having the ionizing radiation reaction products retain sufficient energy to excite a large number of charge excitations in the semiconductor (i.e. relatively thin neutron converting film).

Another common geometry used for neutron detectors comprises a semiconductor material in which predetermined trenches, holes, or pillars, with spatial dimension on the order of a micrometer are prepared, by various etching related techniques such as photolithography, e-beam lithography, etc. Once such structures are prepared, the neutron sensitizing materials are deposited to fill these structures, typically using physical vapor deposition, chemical vapor deposition, electrochemical deposition, etc. These structures are difficult to manufacture and have high fabrication costs.

The present invention relates to different device configurations for detecting of neutrons, particularly at thermal or epithermal energies, using solid state composite films comprising inorganic host semiconductors and guest small molecules and/or particles (e.g. nanoparticle colloids) that contain neutron capture sensitizing atoms, and the methods of fabricating such devices. For example a neutron detector active region can comprise a layer of high mobility host semiconductor in which neutron sensitizing guest material is distributed in all directions throughout it, or a detector active region comprising a multi-layer heterojunction in which one of the layers is comprised of high mobility host semiconductor in which neutron sensitizing guest material is distributed in all directions throughout it, in conjunction with other semiconductor layers create a p-n (or other) junction. Upon a neutron capture in an neutron sensitizing atom in these structures can result in a large number of charge excitations and thus a relatively large detection signal.

The detector active region can comprise one layer or more layers (e.g. a multi-layer heterostructure) where at least one layer comprises of a composite of host semiconductor impregnated with neutron sensitizing material. A multi-layer structure can for example be used for creating heterostructures such as p-n rectifying junction, p-i-n rectifying junction, or schottky diode (created for example by the host—guest composite layer and metallic electrode, or other rectifying junction structures). A layer of doped inorganic host semiconductor impregnated with guest neutron sensitizing materials in conjunction with one or more other doped or non-doped semiconductor layers or semiconductor substrate (containing or not-containing guest neutron sensitizing materials) can form such p-n rectifying junction, p-i-n rectifying junction, other junctions, or Schottky diode.

Aspects of the present invention are also related to fabricating such composite film(s) that constitute part or the entire neutron detector active region using film deposition from solution or paste. These solutions or pastes may contain some combination of materials such as: precursor molecules of the host inorganic semiconductor material, other material that leads to doping of the semiconductor material, precursor molecules for the guest neutron sensitizing material, doped or non-doped semiconductor particles (e.g. semiconductor colloids), and colloids that contain neutron sensitizing atoms. These solutions or pastes can be deposited using various film deposition methods including, doctor blade, screen printing, spray pyrolysis, roll coating, slot die coating, gravure printing, flexographic drum printing, inkjet printing, electrodeposition, chemical bath deposition, and other film deposition methods.

Such methods include for example a fabrication of p-n junction using deposition onto p-type crystalline or polycrystalline semiconductor of a solution containing blend of precursor molecules (or colloids) for n-type host inorganic semiconductor and guest neutron sensitizing colloids suspended in a solvent.

Some of the above film deposition techniques can be followed by post-deposition heat treatment steps for initiating processes such as synthesis of the doped or the non-doped inorganic host semiconductor material (typically by formation of semiconductor nanoparticles through chemical reaction of the semiconductor precursor molecules), synthesis of the guest neutron sensitizing material (through chemical reaction of the precursor molecules of these material), film drying (e.g. elimination solvents), elimination of undesired chemical reaction products, and sintering of the material (e.g. sintering of host semiconductor colloids formed as by chemical reaction of the precursor molecules, or sintering of semiconductor colloids added into the starting solution or paste). The above heating treatment steps results in the formation of densified solid composite film(s) of the host semiconductor with the guest neutron sensitized material distributed through it. The starting materials are chosen so that undesired reaction products are volatile and can be eliminated from the solid film during film deposition and heating treatment.

Other variations of film synthesis and deposition methods are possible; for example, the solution or paste can contain host semiconductor precursor molecules and guest colloids containing neutron sensitizing atoms that are chemically stable at the temperatures used during deposition and post deposition heating treatments. The resulting densified composite film(s) comprise host inorganic semiconductor film(s) that transport the charge excitations generated upon a neutron capture in the neutron sensitizing atoms imbedded in the detector active region.

Other post film fabrication treatments may be required in order for example to enhance carrier transport properties and optimize doping levels in the inorganic host semiconductor in the composite film and in other layers in the detector active region. These may include for example dipping fabricated film(s) in a solution containing specific molecules or exposure films to gases (e.g. POCl₃, O₂, and N₂ used for example for silicon films in order to adjust the doping levels, create silicon oxide, or silicon nitride film, respectively) in conjunction with heat treatment(s) to facilitate diffusion of the gas molecules in the solid film(s).

### Technical Description

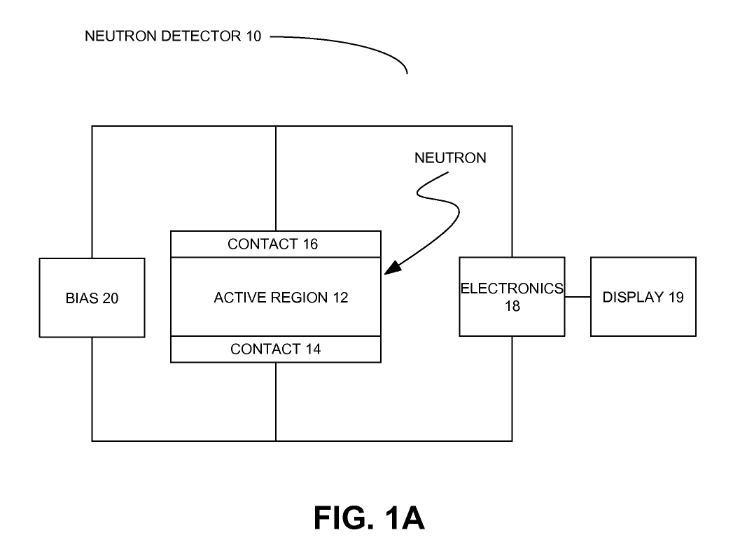

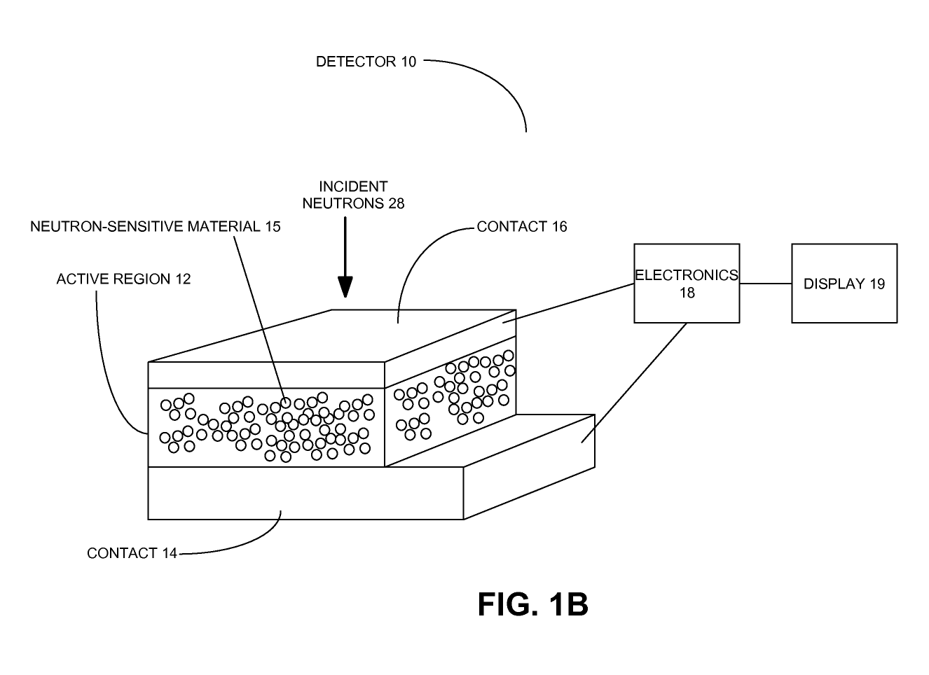

FIG. 1A is a schematic diagram of a neutron detector 10 according to one preferred embodiment of the present invention. The neutron detector 10 includes an active region 12, comprising a layer or multi-layer structure, typically sandwiched between two electrodes or contacts 14, 16, and is connected to detection electronics (e.g. charge sensor and multi channel analyzer, etc.) 18 and display 19. The contacts 14 and 16 can be manufactured such that both contacts 14 and 16 are on one surface of the detector 10 if desired. Further, bias 20 can be optionally used to increase the sensitivity of the detector 10.

The active region 12, as shown in more detail in FIG. 1B, can be a layer comprising a host inorganic semiconductor (e.g. ZnSe, ZnO, CuInS₂ CdSe, CdS, Si, GaP, GaAs, etc.) which is impregnated with neutron sensitizing material 15, e.g., colloids containing neutron sensitizing atoms, etc., that are distributed in a two-dimensional or three-dimensional fashion and in a relatively uniform manner throughout the host semiconductor and thus the active region 12. The neutron sensitizing material 15 may be distributed in other ways, in that the neutron sensitizing material 15 may be randomly distributed in active regions 12, may be a plurality of different types of neutron sensitizing materials 15 that are impregnated in the active region 12, etc., however, the neutron sensitizing material 15 is generally distributed in a relatively uniform manner across a large surface area of the detector 10, such that the detector 10 is sensitive to incident neutrons across one or more surfaces of detector 10.

The active region 12, as shown in more detail in FIG. 1C, can also comprise a composite layer of host inorganic semiconductor 11 (e.g. ZnSe, ZnO, CuInS₂ CdSe, CdS, Si, GaP, GaAs, etc.) which is impregnated with colloids, containing neutron sensitizing atoms (that are distributed throughout the host semiconductor 11 as described with respect to FIG. 1B) that is deposited onto a doped semiconductor substrate (wafer) 13 such that a p-n junction is created.

The host semiconductor in the active region 12 transports the charge carriers that have been excited following a neutron 28 capture in the detector active region 12 (e.g. in one of the neutron sensitizing atoms 15 in the guest material). Various configurations of the active layer 12 include composites of the host semiconductor material 11 with other materials (e.g. the neutron sensitizing guest materials 15), or multi-layer structures comprising multi-layer heterostructures needed for fabricating p-n junction, p-i-n junctions, Schottky junctions, and other device 10 configurations.

The neutron sensitizing material in the detector active layer 12 contain one or more types of neutron capturing atoms in the guest material 24 such as ¹⁰B, ⁶Li, ¹⁵⁷Gd, ²³⁵U, ²³⁹Pu, ⁵¹V, and ^{1O3}Rh. When a thermal neutron 28 is captured in the guest material 24 (and/or 26), an exothermic reaction occurs that typically results in the generation of charged particles in the guest material (e.g. alpha particles) with high kinetic energy. As these particles thermalize, charge carriers (e.g. electrons) are excited in the active region 12, and then transported to the contacts 14 and 16 and the current pulse generated by these charge carriers is detected by the electronics 18. The current pulse due to these generated charge carriers constitutes the detection signal for the neutron captured in the detectors, a signal that can be read out electronically.

For example, a most common reaction for the conversion of slow neutrons into directly detectable particles is the ¹⁰B(n, α)⁷₃Li reaction, upon which reaction products of ⁷Li and ⁴α particles are generated:

₀¹n+₅¹⁰B→₂^{4α+}₃⁷Li (1)

The energy liberated in the reaction following a neutron capture is very large (2.31 MeV or 2,792 MeV), and this energy is imparted onto the reaction products (⁷Li and α particles). The ⁷Li and a particles thermalize in the active region 12 and thereby excite mobile electrons and holes in the active region 12, which generates a current pulse in an externally biased detector (from bias 20) or due to a built-in potential (e.g. at the depletion region of a p-n junction in the active region 12) that constitutes the neutron detector detection signal, which is then forwarded to the electronics 18.

The present invention contemplates the use of solutions or pastes containing precursors molecules or colloids of the host and the guest inorganic materials allows for the fabrication of large area, lightweight neutron detectors 10 using non-vacuum film deposition techniques (e.g., spray pyrolysis, inkjet printing, doctor blading, chemical bath deposition, electrodeposition, screen printing, etc.), which can be done in conjunction with thermal evaporation of some of the detector layers (e.g. the contacts 14 and 16), and with doped or non-doped crystalline or poly-crystalline semiconductor substrates or semiconductor films. As a result, the neutron detectors 10 are inexpensive, and can be fabricated in large areas, and be configured in large detector arrays if desired. In addition, these large area systems can have any number of different shapes, such as cylindrical, hemispherical, rectangular, etc.

For structures such as p-n junction or other rectifying junctions, one layer, or more layers in the multi-layered structure, of the neutron detector active region can be fabricated by the above techniques (e.g. from solutions or pastes), or by deposition of solution or paste onto a predetermined doped or non-doped crystalline or poly-crystalline semiconductor wafer that functions as the p-type or the n-type semiconductor material to form junctions such as p-n, p-i-n, other junctions, or Schottky junctions.

Various combinations of deposition methods and starting materials are possible, such as: 1. starting solution or paste comprising of a solvent and blends of colloids, of typical size between nanometer to few micrometers, of the host semiconductor material and of the guest neutron sensitizing material; 2. starting solution or paste comprising of a solvent and blends of precursor molecules for the host semiconductor and possibly for the guest neutron sensitizing material; 3. starting solution or paste comprising of blends of precursor molecules and colloids of the host semiconductor and neutron sensitizing material; 4. Chemical bath deposition, using precursor materials for the host semiconductor host and neutron sensitizing guest materials; 5. Electrodeposition, using precursor materials for the host semiconductor and neutron sensitizing guest material. Other layers (e.g. semiconductor layers) in a multilayer heterostructures can be deposited using solution or paste.

After the layer(s) deposition, heat treatment post-processing steps may or may not be required. Typically, thermal processing is used for facilitating formation of densified films (e.g. composite of the host and guest film or other semiconductor films in a multi-layer structure). The heating treatment accelerate colloid (e.g. nanoparticle) formation when the starting solution or paste contain precursor molecules as well as sintering of colloids, typically at a significant reduced temperatures compared to the melting temperatures of a constituents bulk materials in the film. Post film deposition can be used for annealing the host matrix and thereby enhancing the transport properties (i.e. higher carrier mobility).

Other post film fabrication treatments may be required in order to enhance carrier transport properties, optimize doping levels, and optimize doping profile in the host semiconductor composite film and in other semiconductor films. These treatments include dipping the fabricated film(s) in solution containing specific molecules (e.g. dipping CdS films in solution containing chlorine molecules), or exposure of the densified film(s) to gases (e.g. POCl₃, O₂, and N₂ used for silicon films in order to enhance doping level or create silicon oxide or silicon nitride films, respectively) in conjunction with heat treatment to facilitate diffusion of the gas molecules in the solid film(s).

These methods of fabrication facilitate a simple way of incorporating neutron sensitizing guest material such as particles (e.g. ¹⁰BN colloids) or molecules within the composite film by blending such guest materials with the inorganic host semiconductor precursor molecules or colloids in the starting solution or paste. After heating treatments and other post-deposition processing steps, the guest neutron sensitizing material (e.g. colloids) are distributed in all directions throughout the host semiconductor matrix. Such methods can be used for the fabrication the various other layers in the multi-layer heterostructures (p-n junctions, p-i-n junctions, other rectifying junctions or Schottky junction)

FIGS. 1B and 1C illustrate construction configurations in accordance with one or more embodiments of the present invention.

### Embodiments of the Present Invention

Fabrication steps such as the ones involved in the fabrication of a neutron detector active region 12 have been demonstrated for fabricating CdSe, CdS, CuInS2 host semiconductor films that were deposited using solution of the semiconductor precursor moleculed with or without BN neutron sensitizing guest colloids. Each semiconductor film system chosen has film fabrication routes that are specific to it. The present invention describes several embodiments for manufacturing the active region 12, including embodiments for fabricating CdSe host semiconductor composites that exhibit good carrier transport properties, and other embodiments that are sensitive to excitation by alpha particles (generated using a ²¹⁰Po source).

### Example 1

A solution contained CdCl₂ (0.1 mmol., with purity of 99.995%), seleneourea (0.1 mmol., with purity of 99.95%) and 1.0 mL butylamine. The butylamine functions as stabilizing ligand that is attached to the nucleating nanoparticles that are formed mostly during the annealing processing step and as a solvent for the precursor materials. The solution also contained BN colloids with average diameter of 0.5 micrometer. This solution was drop-cast on a substrate, then dried at relatively low temperature (30-200 ° C.), and after that annealed at a temperature range of 200-600 ° C., a process that resulted in a solid composite film of CdSe and BN.

Films of CdSe and CdS fabricated using the above approach demonstrated excellent carrier transport properties. Measurements of both the steady-state and transient photoconductivity on these systems indicated a large signal response and long carrier lifetimes.

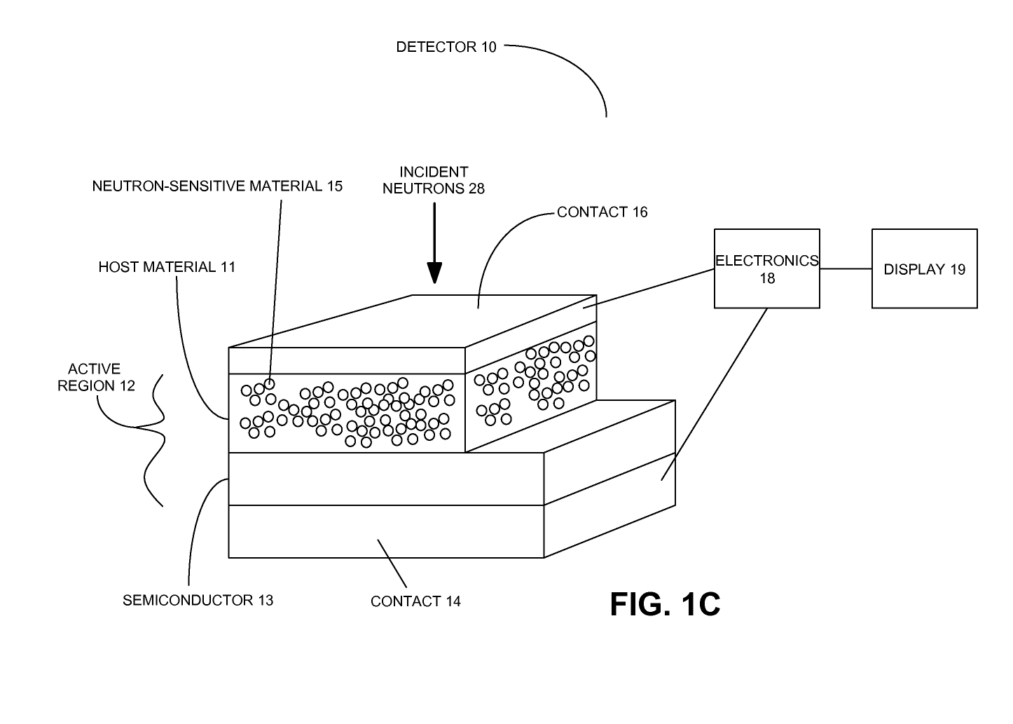

FIG. 2 displays the steady-state photoconductivity action spectrum of a CdSe film that was fabricated by drop casting the CdSe precursor solution onto an alumina substrate, followed by film drying and sintering fabrication steps. The device used was a photoconductive Auston switch that has in-plane Au metallic electrodes, separated by a 50 μm gap (that defines the sample length). The photoconductivity spectrum obtained from this device is plotted in responsivity versus photon wavelength. The peak photoconductive responsivity of ˜18 A/W at 705nm with the relatively low applied electric field of 5×10³ V/cm corresponds to carrier collected per incident photon (IPCE) of over 3100%, demonstrating an excellent photoconductive performance.

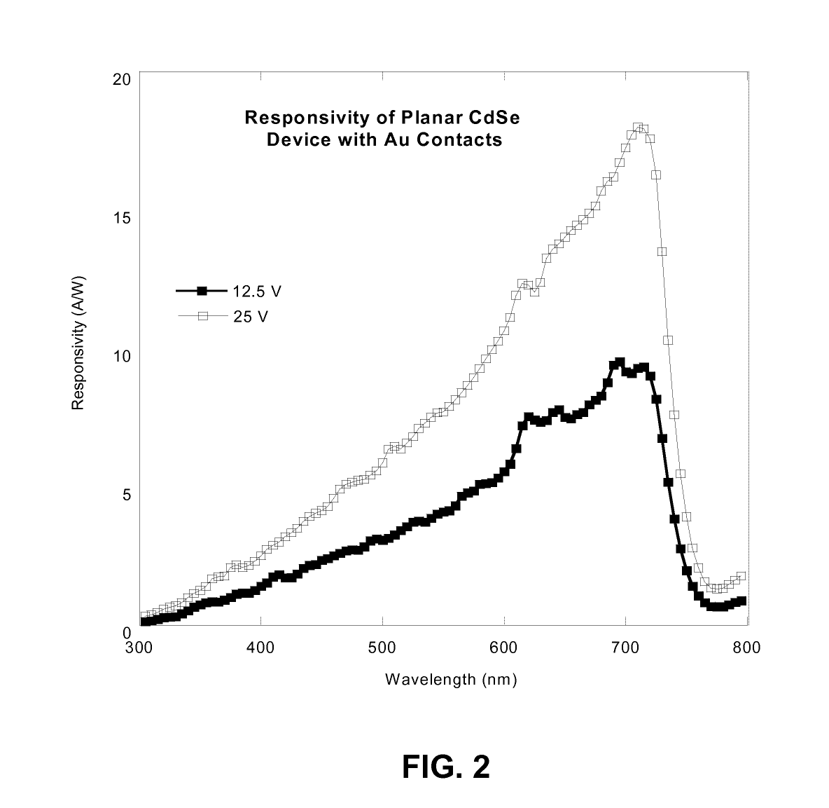

The transient photoconductivity of the same sample, measured in a temporal regime of 100 ps−5 μs, is shown in FIG. 3. The data in FIG. 3 indicates a fast photoconductive response, limited by the overall temporal resolution of the measuring system (about 100 ps), and a relative initial high rate of photocurrent decay that is followed by a slower one that persists to the millisecond time regime.

This approach to the fabrication of host semiconductor composite or the fabrication of multi-layered structures can also be applied to other semiconductor systems e.g., ZnSe, ZnO, CuInS₂, etc.

### Example 2

Devices were fabricated using a solution containing the semiconductor precursor molecules and neutron sensitizing material. The devices were configured in geometry similar the one applicable to neutron detector active layer and were tested in terms of their signal response to excitation by alpha particles which were generated by a ²¹⁰Po source.

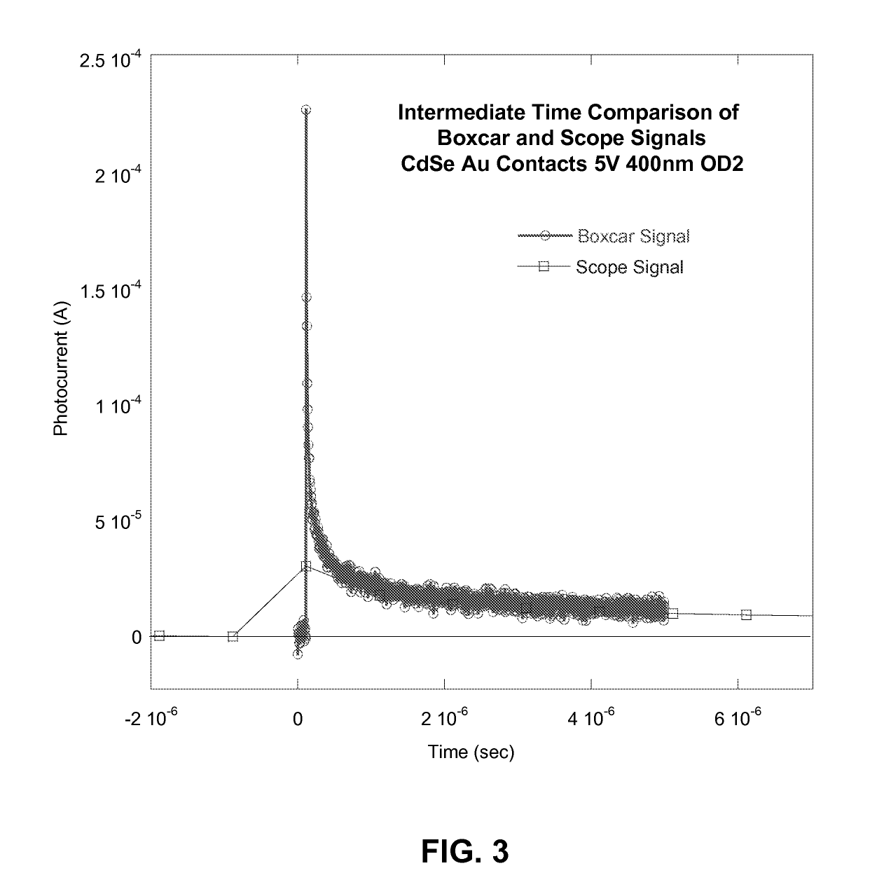

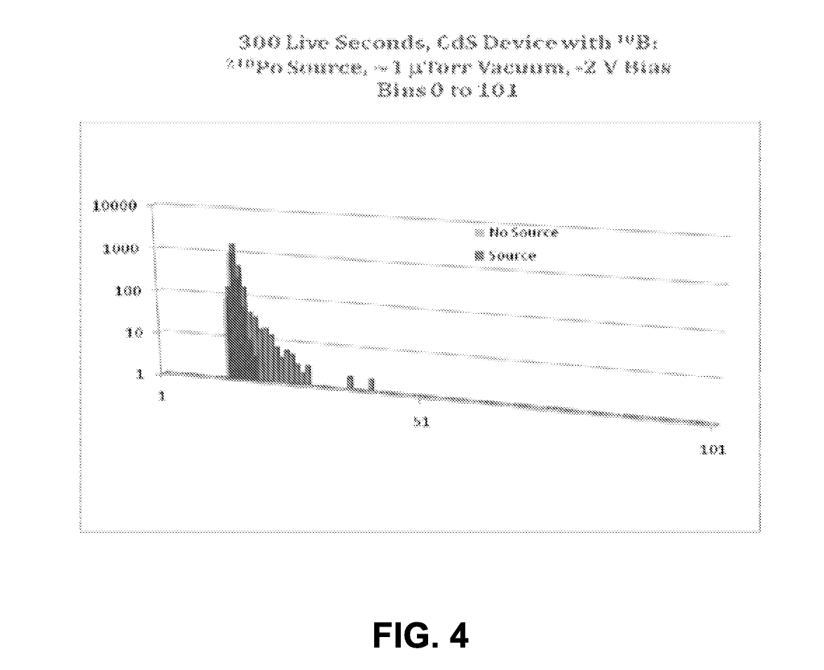

FIGS. 4 and 5 display the Multi Channel Analyzer spectra obtained from such a device. The data exhibit detection efficiency for alpha particles of about 5% from a device that had 40% volume content of neutron sensitizing material distributed in the host semiconductor. The data indicate that such impregnated semiconductor would function as a neutron detector active layer, validating the utility of the device geometry, device structure, and the fabrication routes using solution or paste described in this application.

### Example 3

Other applicable non-vacuum techniques of film fabrication, for single composite or multi-layer structures, are possible. Chemical bath deposition refers to deposition of films on solid substrate placed in the bath due to the reaction occurring in the bath. This technique, has been used for the fabrication of p-n junctions and p-i-n junction and other structures. There are varieties of methods of implementing this approach and a variety of mechanisms that can be utilized (e.g. ion-by-ion, hydroxide cluster, and complex-decomposition). For example, one well known pathway for deposition for example of CdS is by preparing Cd salt in solution to which sulphide ions (such as H₂S) are added, resulting in precipitation of CdS on a substrate placed in the chemical bath). This chemical bath deposition approach has been used extensively for various material systems such as chalcogenide, silver halides, elemental Se, and others, and could be efficient and cost effective methods of film deposition to be used possibly in conjunction with other deposition techniques for the fabrication of neutron detector active layer.

### Example 4

Spray pyrolysis is a process in which a film is deposited by spraying a solution on a heated surface, where the precursor material constituents react to form a chemical compound. The chemical reactants are selected such that the products other than the desired compound are volatile at the temperature of deposition or the temperature of the post-processing of thermal annealing. The process has been demonstrated for the fabrication of many semiconductor systems such as CuInGaSe (CIGS), CuInSe₂ (CIS), ZnO and other systems; currently this approach is utilized in commercial production of thin film solar cells. Other deposition techniques could be efficient and cost effective methods of film deposition to be used in conjunction with spray pyrolysis deposition for the fabrication of neutron detectors.

### Example 5

Electrodeposition is a well-known approach for film deposition that has proven useful for fabricating low-cost, large area multi-layer film structures of solar cells and other devices. It is a usual practice to electrodeposit semiconducting materials using a three-electrode system, namely cathode, anode and a reference electrode. For example, for CuInSe₂, the electrolytic cell used by some researchers comprised a glass/conducting glass or metallic working cathode, high purity graphite rod as an anode and an aqueous electrolyte containing required ions of Cu, In and Se. A typical electrolyte contained at least 4 N purity 0.001 M CuSO₄, 0.004 M In₂(SO₄)₃ and 0.008 M H₂SeO₃ dissolved in de-ionized water. The pH value can be adjusted adding H₂SO₄ to the solution. Multiple-layer device structures (e.g. n-n-i-p) can be fabricated by using alternate solutions that contained different precursor materials and/or altering the ions concentration in the bath as well as other various, immersing the layer in ionic solution after the layer deposition, and other methods. Electrodeposition can be used for the fabrication of a number of layers possibly in conjunction with other deposition techniques (e.g. chemical bath, screen printing, doctor blading, and spray pyrolysis, and others for other layers in the neutron detector structure.

As a result of implementing any of the above techniques to film deposition, the fabrication of neutron detectors are relatively inexpensive, and they can be fabricated in large areas and arranged in large arrays. In addition, these large area systems can have any number of different shapes, such as cylindrical, hemispherical, rectangular, etc.

### Process Chart

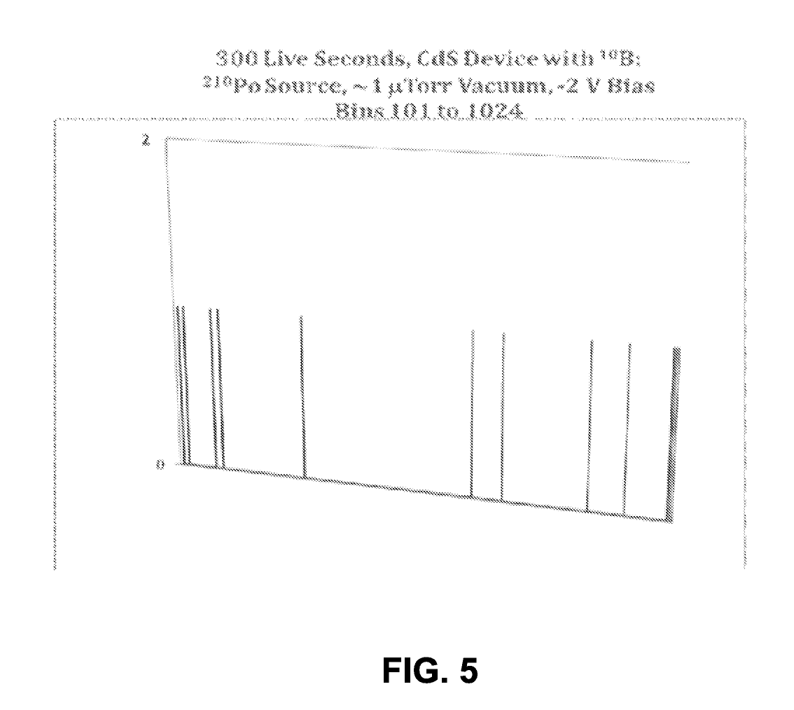

FIG. 6 illustrates a process chart in accordance with one or more embodiments of the present invention.

Box 600 illustrates exposing an active region comprising a heterojunction wherein at least one layer of the active region comprises a host semiconductor having neutron sensitizing guest material distributed in the host semiconductor, at least one of the host semiconductor and the neutron sensitizing guest material being deposited through at least one process selected from a list consisting of: non-vacuum film deposition, roll coating, slot die coating, gravure printing, flexographic drum printing, inkjet printing, doctor blade, drop casting, screen printing, spray pyrolysis, spin coating, drop casting, electrodeposition, and chemical bath deposition.

Box 602 illustrates generating, within the active region, a detection signal when neutrons are detected.

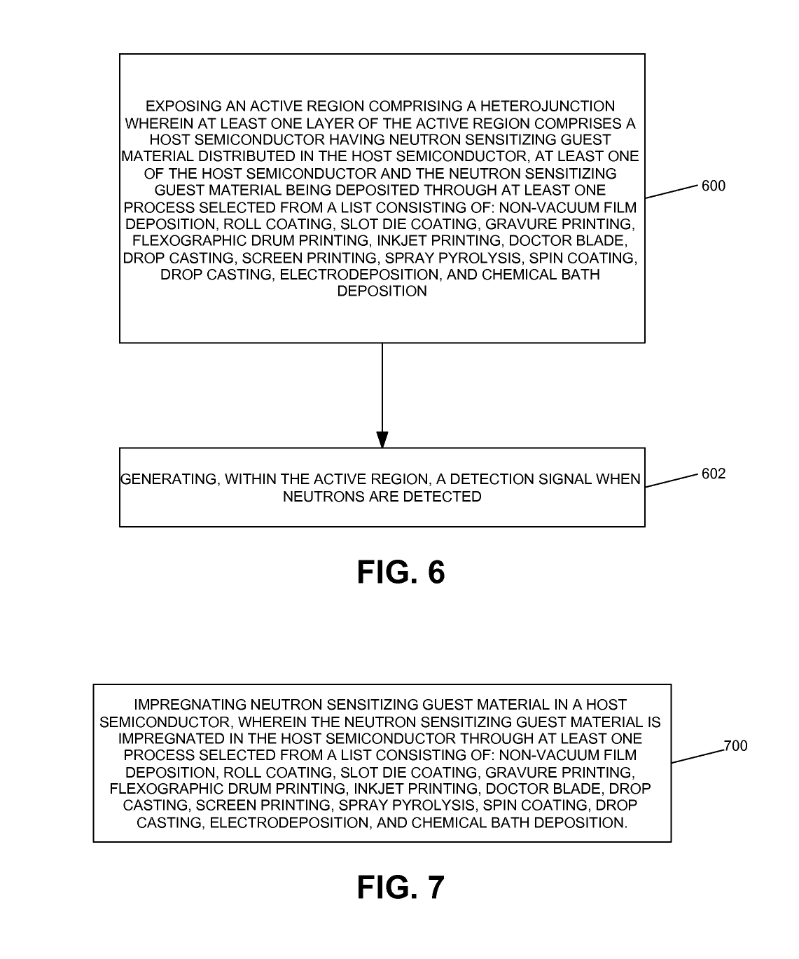

FIG. 7 illustrates a process chart in accordance with one or more embodiments of the present invention.

Box 700 illustrates impregnating neutron sensitizing guest material in a host semiconductor, wherein the neutron sensitizing guest material impregnates the host semiconductor through at least one process selected from a list consisting of: non-vacuum film deposition, roll coating, slot die coating, gravure printing, flexographic drum printing, inkjet printing, doctor blade, drop casting, screen printing, spray pyrolysis, spin coating, drop casting, electrodeposition, and chemical bath deposition.

### REFERENCES

The following references are incorporated by reference herein.

1. G. E. Knoll, Radiation detection and measurement, Third edition (Wiley, New York, 2000).

2. J. K. J. van Duren, C. Leidholm, A. Pudov, M. R. Robinson, Y. Roussillon, The next generation of thin-film photovoltaics, Materials Research Society Symposium Proceedings, Volume 1012, (2007).

3. I. M. Dharmadasa, R. P. Burton, M. Simmonds, Solar Energy Materials & Solar Cells 90, 2191 (2006).

4. Y. Hashimoto, N. Kohara, T. Negami, N. Nishitani, T. Wada, Solar Energy Materials & Solar Cells 50, 71 (1998).

5. Thin Film Solar Cells (Ed. Y. Hamakawa, Springer, Berlin 2004).

6. Liang Li, Nelson Coates, and Daniel Moses, Solution-Processed Inorganic Solar Cell Based on in Situ Synthesis and Film Deposition of CuInS2 Nanocrystals, Journal of the American Chemical Society 132, 22 (2010).

7. Nelson E. Coates, Huiqiong Zhou, Stephan Kraemer, Daniel Moses, Solution-based in-situ Synthesis and Fabrication of Ultrasensitive CdS Photoconductors, Advanced Materials (to be published).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto and the full range of equivalents to the claims.

What is claimed is:

1. A neutron detector, comprising:
an active region comprising:
an inorganic host semiconductor material, and
a neutron sensitizing guest material distributed within the host semiconductor material, the inorganic guest material comprising a plurality of neutron capturing atoms, such that the host semiconductor material transports charge carriers excited following a neutron absorption in the neutron sensitizing guest material, at least one of the host semiconductor material and the neutron sensitizing guest material being deposited through at least one process selected from a list consisting of: non-vacuum film deposition, roll coating, slot die coating, gravure printing, flexographic drum printing, inkjet printing, doctor blade, drop casting, screen printing, spray pyrolysis, spin coating, drop casting, electrodeposition, and chemical bath deposition; and
detection electronics, coupled to the active layer, wherein the active layer provides a detection electrical signal for the neutron to the detection electronics.

2. The neutron detector of claim 1, wherein the host semiconductor material comprises a host semiconductor material blended with a guest semiconductor material.

3. The neutron detector of claim 1, wherein the host semiconductor material is a doped semiconductor material.

4. The neutron detector of claim 1, wherein the active region comprises a multi-layer heterojunction.

5. The neutron detector of claim 1, wherein the active region comprises one or more of a p-n junction, a p-i-n junction, and a Schottky junction.

6. The neutron detector of claim 1, wherein the active region further comprises a semiconductor layer coupled to the inorganic host semiconductor material.

7. The neutron detector of claim 1, wherein the guest neutron sensitizing material containing neutron capturing atoms of ¹⁰B, ⁶Li, ¹⁵⁷Gd, ²³⁵U, ²³⁹Pu, ⁵¹V, or ^{1O3}Rh.

8. The neutron detector of claim 1, wherein at least one layers in the detector active region is deposited using solution or paste containing precursor molecules or colloids for the host semiconductor material and for the neutron sensitizing guest material through at least one process selected from a list consisting of: non-vacuum film deposition, roll coating, slot die coating, gravure printing, flexographic drum printing, inkjet printing, doctor blade, drop casting, screen printing, spray pyrolysis, spin coating, electrodeposition, and chemical bath deposition.

9. The neutron detector of claim 1, wherein at least a portion of the active region is fabricated using vacuum thermal deposition and at least one remaining layer of the active layer is fabricated using non-vacuum techniques.

10. The neutron detector of claim 1, wherein the active region is sandwiched between two electrodes.

11. A method of detecting neutrons, comprising:
exposing an active region comprising a heterojunction wherein at least one layer of the active region comprises a host semiconductor having neutron sensitizing guest material distributed in the host semiconductor, at least one of the host semiconductor and the neutron sensitizing guest material being deposited through at least one process selected from a list consisting of: non-vacuum film deposition, roll coating, slot die coating, gravure printing, flexographic drum printing, inkjet printing, doctor blade, drop casting, screen printing, spray pyrolysis, spin coating, drop casting, electrodeposition, and chemical bath deposition, and
generating, within the active region, a detection signal when neutrons are detected.

12. A method for making a neutron detector, comprising:
impregnating neutron sensitizing guest material in a host semiconductor, wherein the neutron sensitizing guest material is impregnated in the host semiconductor through at least one process selected from a list consisting of: non-vacuum film deposition, roll coating, slot die coating, gravure printing, flexographic drum printing, inkjet printing, doctor blade, drop casting, screen printing, spray pyrolysis, spin coating, drop casting, electrodeposition, and chemical bath deposition.
